(19) United States
(12) Patent Application Publication
(10) Pub. No.: US 2013/0037859 A1
(43) Pub. Date: Feb. 14, 2013

(54) SEMICONDUCTOR DEVICE AND PROGRAMMING METHOD THEREOF

(71) Applicants: Huicai Zhong, San Jose, CA (US); Qingqing Liang, Lagrangeville, NY (US); Chao Zhao, Kessel-Io (BE); Huilong Zhu, Poughkeepsie, NY (US)

(72) Inventors: Huicai Zhong, San Jose, CA (US); Qingqing Liang, Lagrangeville, NY (US); Chao Zhao, Kessel-Io (BE); Huilong Zhu, Poughkeepsie, NY (US)

(21) Appl. No.: 13/321,852

(22) PCT Filed: Aug. 12, 2011
(86) PCT No.: PCT/CN11/78327

§ 371 Date: Nov. 22, 2011

(51) Int. Cl. H01L 27/10; H01L 21/326; H01L 23/522; H01L 29/788; H01L 29/92; H01L 23/525

(52) U.S. Cl. 257/208; 257/532; 257/529; 257/530; 257/774; 257/315; 438/466; 257/E23.145; 257/E29.342; 257/E23.147; 257/E23.149; 257/E29.3; 257/E27.07; 257/E21.327

(57) ABSTRACT

A semiconductor device and a method for programming the same are provided. The semiconductor device comprises: a semiconductor substrate with an interconnect formed therein; a Through-Silicon Via (TSV) penetrating through the semiconductor substrate; and a programmable device which can be switched between on and off states, the TSV being connected to the interconnect by the programmable device. The present invention is beneficial in improving flexibility of TSV application.

This application is a National Phase application of, and claims priority to, PCT Application No. PCT/CN2011/078327, filed on Aug. 12, 2011, entitled “SEMICONDUCTOR DEVICE AND PROGRAMMING METHOD THEREOF”, which claimed priority to Chinese Application No. 201110112295.8, filed on Apr. 29, 2011. Both the PCT Application and Chinese Application are incorporated herein by reference in their entireties.

### FIELD OF THE INVENTION

The present invention relates to the field of semiconductor technology, and particularly to a semiconductor device and a programming method thereof.

### BACKGROUND OF THE INVENTION

Two or more integrated circuits stacked vertically may be packaged into one chip by 3D packaging so that they occupy less space. In 3D packaging, substrates with Through-Silicon Vias (TSVs) for carrying integrated circuits are generally employed. By using TSV technology instead of conventional bonding interconnects for 3D packaging, more logical functionality may be integrated into a small footprint. In addition, by using TSVs, critical paths can be effectively shortened, which may achieve reduced delay and faster device speed.

A method for forming a TSV generally comprises: forming a through hole in a substrate, filling it to form a via such that the via is connected to an interconnect in the substrate, and connecting the via to an interconnection structure on another wafer or chip to achieve 3D packaging.

Conventional TSVs are based on copper interconnect techniques. FIG. 1 to FIG. 5 illustrate a cross-sectional view of an intermediate structure according to a conventional method for forming a TSV.

As shown in FIG. 1, a semiconductor substrate 10 is provided. A semiconductor device, e.g., a MOS transistor, may be formed on the semiconductor substrate 10. In addition, vias or interconnects may be formed on the semiconductor substrate 10.

As shown in FIG. 2, the upper surface of the semiconductor substrate 10 is etched to form an opening 11.

As shown in FIG. 3, a barrier layer 12 is formed to cover bottom and sidewalls of the opening and the upper surface of the semiconductor substrate 10. Then, metal copper 13 is formed on the barrier layer 12 by electroplating to fill the opening. The method may further comprise forming a seed layer on the surface of the barrier layer 12 before formation of the metal copper 13.

As shown in FIG. 4, the metal copper and the barrier layer 12 on the semiconductor substrate 10 are planarized such that the upper surface of the semiconductor substrate 10 is exposed to form a via 13a.

As shown in FIG. 5, the semiconductor substrate 10 is thinned down from its lower surface such that the via 13a is exposed and the opening becomes a through hole penetrating through the semiconductor substrate 10. Thereby formation of the TSV is completed.

Normally, conventional TSVs are eclectically connected to interconnects in the semiconductor substrate. And in 3D packaging, the interconnects are electrically connected with interconnection structures on other substrates by the TSVs. The relationship for connection between the TSV and the interconnect is predetermined, and hence variation thereof may be difficult to meet requirements in practice, resulting in low application flexibility.

More details on the TSV may refer to U.S. Pat. No. 7,683,459 and No. 7,633,165.

### SUMMARY OF THE INVENTION

A problem to be solved by the present invention is to provide a semiconductor device and a programming method thereof, to improve the application flexibility of TSV.

To solve the problem above, the invention provides a semiconductor device, comprising:

a semiconductor substrate with an interconnect formed therein;

a Through-Silicon Via (TSV) penetrating through the semiconductor substrate; and

a programmable device which can be switched between on and off states, the TSV being connected to the interconnect by the programmable device.

Optionally, the programmable device may be a capacitor formed in or on the semiconductor substrate, and has an upper plate electrically connected with the TSV and a lower plate electrically connected with the interconnect.

Optionally, the programmable device may be a capacitor embedded in the TSV. The capacitor may separate the TSV into a first part and a second part, with the first part connected with an upper plate of the capacitor, the second part connected with a lower plate of the capacitor, and the interconnect eclectically connected with the first part or the second part of the TSV.

Optionally, the programmable device may be a fuse or an antifuse formed in or on the semiconductor substrate, and may have one end electrically connected with the TSV and the other end electrically connected with the interconnect.

Optionally, the programmable device may be a fuse or an antifuse embedded in the TSV. The fuse or antifuse may separate the TSV into a first part and a second part, with the first part connected with one end of the fuse or antifuse, the second part connected with the other end of the fuse or antifuse, and the interconnect electrically connected with the first part or the second part of the TSV.

Optionally, the programmable device may be a floating-gate MOS transistor formed in the semiconductor substrate, and may have a source and a drain electrically connected with the TSV and the interconnect, respectively.

Optionally, the programmable device may be one of a microprocessor, a logic control device managed by a Field-Programmable Gate Array (FPGA), a Programmable Logic Controller (PLC) or a Microcontroller.

The present invention also provides a method for programming the semiconductor device above, comprising: programming the programmable device such that the TSV is electrically connected or disconnected to the interconnect.

Compared with the prior art, the embodiments of the present invention may bring the following advantages:

According to the semiconductor device of the embodiments of the present invention, the TSV is connected to the interconnect in the semiconductor substrate via a programmable device, hence the connection or disconnection between the TSV and the interconnect can be realized by programming the programmable device, thereby improving flexibility of TSV application.

The programmable device in the embodiments may be a capacitor, a fuse or an antifuse, which may be formed in the semiconductor substrate, or on the semiconductor substrate, or embedded in the TSV. In addition, the programmable device may also be a floating-gate MOS transistor formed in the semiconductor substrate. All the programmable devices mentioned above can be formed by conventional semiconductor processing techniques, thereby providing good industrial applicability.

### BRIEF DESCRIPTION OF THE DRAWINGS

The above and other objects, features and advantages of the present invention will become more apparent when read in conjunction with the accompanying drawings, in which the same reference numeral indicate the same component. The accompanying drawings may not be drawn to scale, so as not to unnecessarily obscure the essence of the present invention.

FIG. 1 to FIG. 5 are cross-sectional views for illustrating a conventional method for forming a TSV;

FIG. 6 is a cross-sectional view for illustrating a structure of a semiconductor device according to an embodiment of the invention;

FIG. 7 is a cross-sectional view for illustrating a structure of a semiconductor device according to another embodiment of the invention; and

FIG. 8 illustrates a logic structure of a semiconductor device according to an embodiment of the invention.

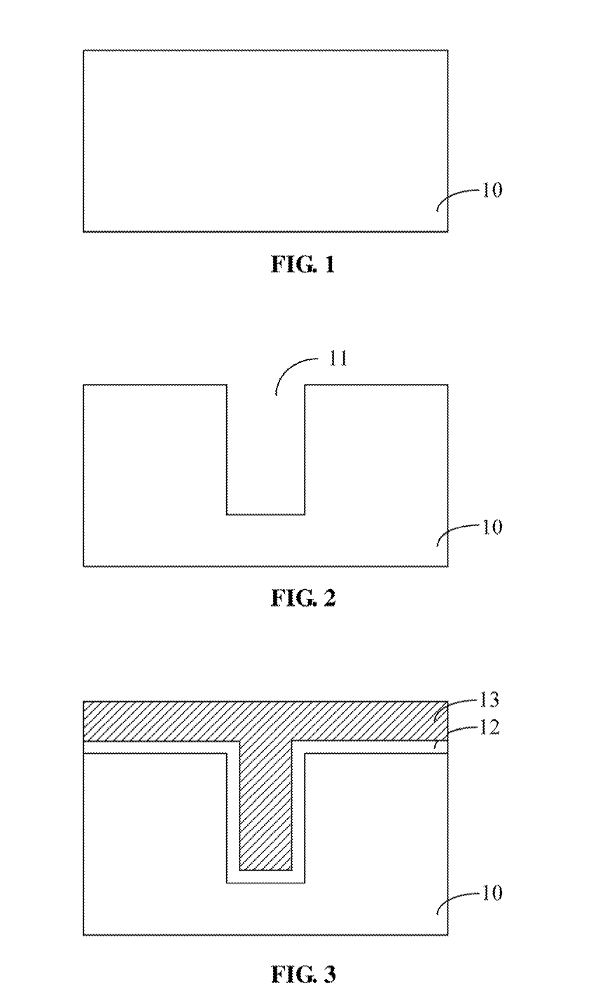

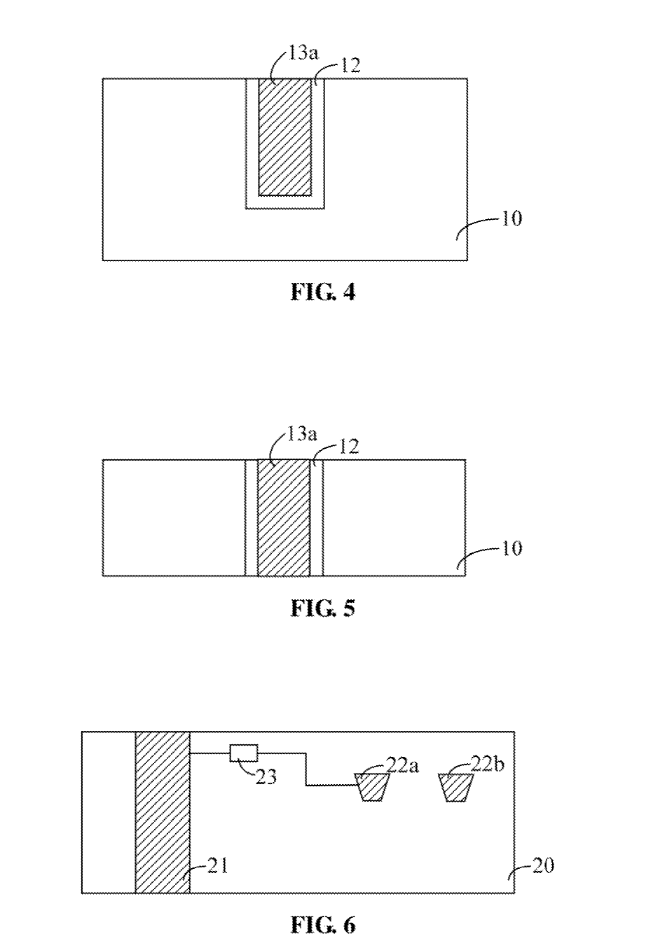

### DETAILED DESCRIPTION OF THE INVENTION

Generally, the conventional TSV formed in the semiconductor substrate is fixed to be connected to a preset interconnect, which provides less flexibility in practice.

In the semiconductor device according to the embodiments of the present invention, the TSV is connected to the interconnect in the semiconductor substrate by a programmable device. Hence the connection or disconnection between the TSV and the interconnect can be achieved by programming the programmable device, thereby improving flexibility in practice.

The programmable device in the embodiments may be a capacitor, a fuse or an antifuse, which may be formed in or on the semiconductor substrate, or embedded in the TSV. In addition, the programmable device may also be a MOS transistor, which has a floating gate, formed in the semiconductor substrate. All the programmable devices mentioned above can be formed by conventional semiconductor processing techniques, thereby providing good industrial applicability.

For better understanding of the above objects, features and advantages of the invention, the embodiments of the invention will be described in detail hereinafter with reference to the accompanying drawings.

Specific details are described herein for illustrative purpose only. However, the invention can be implemented in ways other than what is described herein, and equivalents can be obtained by those skilled in the art without deviation from the scope of the invention. Therefore, the invention is not limited to the embodiments disclosed herein.

FIG. 6 is a cross-sectional view of the structure of a semiconductor device according to an embodiment of the invention, which comprises: a semiconductor substrate 20, with an interconnect 22a formed therein; a TSV 21 penetrating through the semiconductor substrate 20; and a programmable device 23 having switch-on and switch-off states, wherein the TSV is connected to the interconnect 22a by the programmable device 23. In this embodiment, the programmable device 23 may be a capacitor, a fuse, an antifuse or a MOS transistor, which has a floating gate, formed in or on the semiconductor substrate 20. The capacitor, fuse, antifuse, and MOS transistor having a floating gate may be formed along with the interconnect 22a by conventional semiconductor processing techniques, thereby providing good industrial applicability.

The semiconductor substrate 20 may comprise one of: a silicon substrate, a silicon germanium substrate, a III-V compound substrate, a silicon carbide substrate or a multi-layered structure thereof, a silicon-on-insulator structure, and any other semiconductor substrate known by those skilled in the art. A device such as a MOS transistor may be formed in the semiconductor substrate 20. The semiconductor substrate 20 may also comprise a plurality of dielectric layers covering the device such as the MOS transistor. Interconnects 22a and 22b may be formed in the dielectric layers. The interconnect 22a may be a copper interconnect, an aluminum interconnect or the like, and may be electrically connected to the device such as the MOS transistor through an interconnection structure such as a conductive via and a contact via. The programmable device 23 and the interconnects 22a and 22b may be in the same dielectric layer, or in different dielectric layers. In a preferred embodiment, the programmable device 23 may be a capacitor, a fuse or an antifuse formed on the surface of the semiconductor substrate 20, and may be electrically connected to the TSV 21 by a conducting wire arranged on the semiconductor substrate 20. Since the programmable device 23 is on the surface of the semiconductor substrate 20, the manufacturing process is simple.

In a different embodiment where the programmable device 23 is a capacitor comprising an upper plate, a lower plate and a dielectric layer between the upper plate and the lower plate, the TSV 21 may be electrically connected with the upper plate, and the interconnect 22a may be electrically connected with the lower plate. In a normal state, the upper plate may be insulated from the lower plate so that the TSV 21 is disconnected from the interconnect 22a; then, in subsequent 3D packaging, the TSV 21 is not in use and is not used for interconnection between semiconductor substrates. Alternatively, a breakdown voltage may be applied between the upper plate and the lower plate of the capacitor, so that the capacitor is broken down and becomes conductive, and hence the TSV 21 is electrically connected to the interconnect 22a; then, in subsequent applications such as 3D packaging, the interconnect 22a and another semiconductor substrate can be electrically connected by the TSV 21.

In a different embodiment where the programmable device 23 is a fuse or an antifuse, the TSV 21 may be connected with one end of the fuse or antifuse, and the interconnect 22a may be connected with the other end of the fuse or antifuse. In a normal state, the fuse is switched on, or the antifuse is switched off, so that the electrical connection between the TSV and the interconnect 22a is switched on or off correspondingly. In addition, a programming current may be applied to the fuse or antifuse for switching off the fuse or switching on the antifuse, so that the electrical connection between the TSV 21 and the interconnect 22a is switched on or off correspondingly. In this way, the electrical connection between the TSV 21 and the interconnect 22a can be turned on or off conveniently as required in practice.

In a different embodiment where the programmable device 23 is a floating-gate MOS transistor, specifically, a floating-gate MOS transistor used in a memory device such as EPROM, EEPROM and FLASH, the TSV 21 may be electrically connected with one of the source and drain of the floating-gate MOS transistor, and the interconnect 22a may be electrically connected with the other one of the source and drain of the floating-gate MOS transistor. Electrons may be injected into or erased from the floating gate by programming, so as to realize switching for on and off states between the source and drain of the floating-gate MOS transistor, i.e., to switch on or off the electrical connection between the TSV 21 and the interconnect 22a.

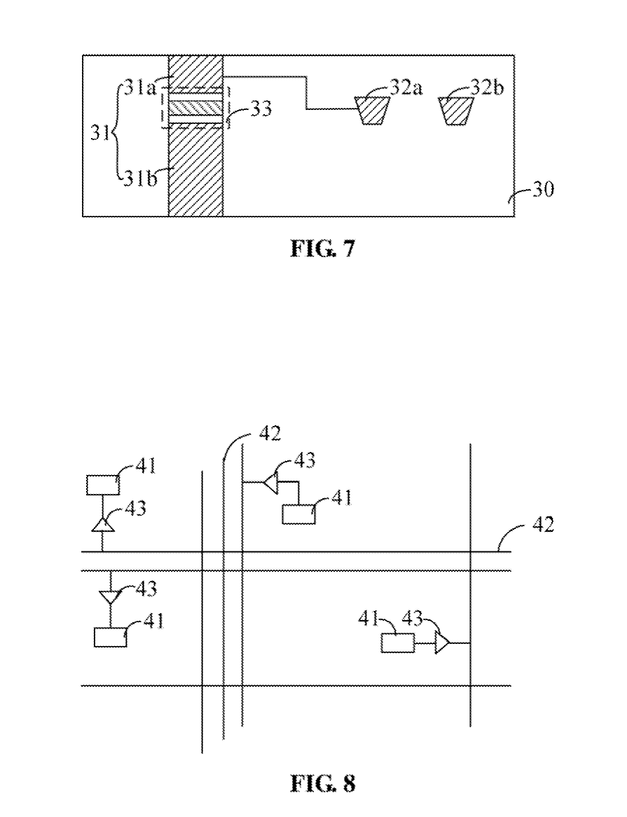

FIG. 7 is a cross-sectional view of a structure for a semiconductor device according to another embodiment of the invention. The semiconductor device comprises: a semiconductor substrate 30 with an interconnect 32a formed therein; a TSV 31, penetrating through the semiconductor substrate 30; and a programmable device 33 which may be switched between on and off states, the TSV 31 being connected to the interconnect 32a by the programmable device 33. In this embodiment, the programmable device 33 may be a capacitor, a fuse or an antifuse embedded in the TSV 31.

The description regarding the materials of the semiconductor substrate 30 is omitted here, and one may refer to the description in the embodiment above. Furthermore, a device such as a MOS transistor, as well as interconnects 32a, 32b may also be formed in the semiconductor substrate 30.

The programmable device 33 such as a capacitor, a fuse or an antifuse may separate the TSV 31 into a first part 31a and a second part 32b. The first part 31a is connected with the upper plate of the capacitor, and the second part 31b is connected with the lower plate of the capacitor. In other embodiments, the first part 31a is connected with one end of the fuse or antifuse, and the second part 31b is connected with the other end of the fuse or antifuse. The interconnect 32a may be electrically connected with the first part 31a or the second part 31b of the TSV 31. In this embodiment, the interconnect 32a may be electrically connected with the first part 31a, and in subsequent 3D packaging, the second part 31b may be connected with another semiconductor substrate.

Similar to the previous embodiment, the electrical connection between the TSV 31 (specifically in this embodiment, the second part 31b of the TSV 31) and the interconnect 32 can be switched on or off by programming the capacitor, the fuse or the antifuse, thereby improving the flexibility of TSV application in practice.

In other embodiments, the programmable device may be a device with logical control functionality in or on the semiconductor substrate, e.g., a microprocessor, a logic control device managed by FPGA, a programmable logic controller or a microcontroller. The electrical connection between the TSV and the interconnect can be switched between on and off states by logic control and programming, thereby improving flexibility of TSV application in practice.

FIG. 8 illustrates the logic structure of a semiconductor device according to an embodiment of the invention, which comprises: a plurality of interconnects 42, a TSV 41 and a programmable devices 43. The TSV 41 is connected to the interconnect 42 by the programmable device 43. The programmable device may be a capacitor, a fuse, an antifuse or a floating-gate MOS transistor, etc. The invention also provides a programming method for the semiconductor device above. As shown in FIG. 8, the programmable device 43 may be programmed such that the electrical connection between the TSV 41 and the interconnect 42 is electrically connected or disconnected, thereby improving flexibility of TSV application.

Although preferred embodiments of the invention are disclosed above, they should not be interpreted as limiting the scope of the invention. Alternations and modifications can be made to the technical solutions of the invention by those skilled in the art based on the technical disclosure herein without deviation from the scope of the invention. Therefore, any alternations, equivalents, or modifications made to the embodiments disclosed herein based on the technical essentials of the invention without deviation from the scope of the invention should fall within the scope of the invention.

1. A semiconductor device, comprising:
a semiconductor substrate with an interconnect formed therein;
a Through-Silicon Via (TSV) penetrating through the semiconductor substrate; and
a programmable device which can be switched between on and off states, the TSV being connected to the interconnect by the programmable device.

2. The semiconductor device according to claim 1, wherein the programmable device is a capacitor formed in or on the semiconductor substrate, and has an upper plate electrically connected with the TSV and a lower plate electrically connected with the interconnect.

3. The semiconductor device according to claim 1, wherein the programmable device is a capacitor embedded in the TSV, and the capacitor separates the TSV into a first part and a second part, and wherein the first part is connected with an upper plate of the capacitor, the second part is connected with a lower plate of the capacitor, and the interconnect is eclectically connected with the first part or the second part of the TSV.

4. The semiconductor device according to claim 1, wherein the programmable device is a fuse or an antifuse formed in or on the semiconductor substrate, and wherein one end of the fuse or antifuse is electrically connected with the TSV and the other end is electrically connected with the interconnect.

5. The semiconductor device according to claim 1, wherein the programmable device is a fuse or an antifuse embedded in the TSV, and the fuse or antifuse separates the TSV into a first part and a second part, and wherein the first part is connected with one end of the fuse or antifuse, the second part is connected with the other end of the fuse or antifuse, and the interconnect is electrically connected with the first part or the second part of the TSV.

6. The semiconductor device according to claim 1, wherein the programmable device is a floating-gate MOS transistor formed in the semiconductor substrate and has a source and a drain electrically connected with the TSV and the interconnect, respectively.

7. The semiconductor device according to claim 1, wherein the programmable device is one of a microprocessor, a logic control device managed by a Field-Programmable Gate Array (FPGA), a Programmable Logic Controller (PLC) or a Microcontroller in or on the semiconductor substrate.

8. A method for programming the semiconductor device according to claim 1, comprising: programming the programmable device such that the TSV is electrically connected or disconnected to the interconnect.

9. A method for programming the semiconductor device according to claim 2, comprising: programming the programmable device such that the TSV is electrically connected or disconnected to the interconnect.

10. A method for programming the semiconductor device according to claim 3, comprising: programming the programmable device such that the TSV is electrically connected or disconnected to the interconnect.

11. A method for programming the semiconductor device according to claim 4, comprising: programming the programmable device such that the TSV is electrically connected or disconnected to the interconnect.

12. A method for programming the semiconductor device according to claim 5, comprising: programming the programmable device such that the TSV is electrically connected or disconnected to the interconnect.

13. A method for programming the semiconductor device according to claim 6, comprising: programming the programmable device such that the TSV is electrically connected or disconnected to the interconnect.

14. A method for programming the semiconductor device according to claim 7, comprising: programming the programmable device such that the TSV is electrically connected or disconnected to the interconnect.
